(19) United States
(12) Patent Application Publication
(10) Pub. No.: US 2025/0142835 A1
(43) Pub. Date: May 1, 2025

(54) SEMICONDUCTOR DEVICE, MEMORY DEVICE, AND METHOD OF MANUFACTURING THE SEMICONDUCTOR DEVICE

(71) Applicant: Samsung Electronics Co., Ltd., Suwon-si (KR)

(72) Inventors: Yunseong LEE, Suwon-si (KR); Sijung YOO, Suwon-si (KR); Seunggeol NAM, Suwon-si (KR); Kihong KIM, Suwon-si (KR); Yoonsang PARK, Suwon-si (KR); Sanghyun JO, Suwon-si (KR)

(73) Assignee: Samsung Electronics Co., Ltd., Suwon-si (KR)

(21) Appl. No.: 18/927,200

(22) Filed: Oct. 25, 2024

(30) Foreign Application Priority Data
Oct. 26, 2023 (KR) 10-2023-0145108
Apr. 8, 2024 (KR) 10-2024-0047362

(51) Int. Cl. H10B 51/30; H10B 51/20

(52) U.S. Cl. CPC H10B 51/30; H10B 51/20

(57) ABSTRACT

A semiconductor device, a memory device, and a method of manufacturing the semiconductor device are disclosed. The semiconductor device includes a semiconductor substrate, a ferroelectric layer provided on the semiconductor substrate, an aluminum oxide layer provided on the ferroelectric layer, and a gate electrode provided on the aluminum oxide layer, wherein the aluminum oxide layer includes aluminum, oxygen, and hydrogen, and wherein a content of oxygen in the aluminum oxide layer is more than about 1.5 times and about 2 times or less a content of aluminum in the aluminum oxide layer.

### CROSS-REFERENCE TO RELATED APPLICATION

This application is based on and claims priority under 35 U.S.C. § 119 to Korean Patent Application Nos. 10-2023-0145108, filed on Oct. 26, 2023, and 10-2024-0047362, filed on Apr. 8, 2024, in the Korean Intellectual Property Office, the disclosures of which are incorporated by reference herein in their entirety.

### BACKGROUND

### 1. Field

The disclosure relates to a semiconductor device, a memory device, and a method of manufacturing the semiconductor device.

### 2. Description of the Related Art

Ferroelectrics are materials having ferroelectricity, which means that the internal electric dipole moments of such materials are aligned to maintain spontaneous polarization even when no electric field is applied from the outside. Recently, research has been conducted to implement memory devices with multi-levels and increase a memory window by applying ferroelectrics to memory devices.

### SUMMARY

Provided are a semiconductor device, a memory device, and a method of manufacturing the semiconductor device.

Additional aspects will be set forth in part in the description which follows and, in part, will be apparent from the description, or may be learned by practice of the presented embodiments of the disclosure.

According to an aspect of at least one example embodiment, a semiconductor device includes a semiconductor substrate; a gate electrode; a ferroelectric layer between the semiconductor substrate and the gate electrode; and an aluminum oxide layer between the ferroelectric layer and the gate electrode, wherein the aluminum oxide layer includes aluminum, oxygen, and hydrogen, and wherein a content of the oxygen in the aluminum oxide layer is within of range of more than about 1.5 times to about 2 times a content of the aluminum in the aluminum oxide layer.

A content of the hydrogen in the aluminum oxide layer may be within a range of 1.5 atomic percentage (at %) to about 4 atomic percentage (at %).

A thickness of the aluminum oxide layer may be within a range of about 0.3 nm to about 10 nm.

A density of the aluminum oxide layer may be within a range of about 3.00 g/cm³ to about 3.95 g/cm³.

The semiconductor device may further include a current leakage prevention layer between the aluminum oxide layer and the gate electrode, wherein the current leakage prevention layer may include at least one of MgO, SiO, YO, LaO, or a combination thereof.

The semiconductor device may further include a current leakage prevention layer provided between the ferroelectric layer and the aluminum oxide layer, wherein the current leakage prevention layer includes at least one of MgO, SiO, YO, LaO, or a combination thereof.

The ferroelectric layer may include at least one of hafnium oxide, zirconium oxide, hafnium-zirconium oxide, perovskite, or a combination thereof.

A content of hydrogen in the aluminum oxide layer may decrease in a thickness direction from the ferroelectric layer toward the gate electrode.

The aluminum oxide layer may include a first aluminum oxide layer including the hydrogen and a second aluminum oxide layer including a lower hydrogen content than the first aluminum oxide layer, wherein the second aluminum oxide layer is between the first aluminum oxide layer and the gate electrode.

A thickness of the second aluminum oxide layer may be greater than a thickness of the first aluminum oxide layer.

According to another aspect of at least one example embodiment, a memory device includes a substrate; a plurality of gate electrodes stacked in a direction perpendicular to the substrate; a channel layer extending through the plurality of gate electrodes in the direction perpendicular to the substrate; a ferroelectric layer on the channel layer such that the ferroelectric layer is between the channel layer and the plurality of gate electrodes; and an aluminum oxide layer on the ferroelectric layer such that the aluminum oxide layer is between the ferroelectric layer and the plurality of gate electrodes; and wherein the aluminum oxide layer includes aluminum, oxygen, and hydrogen, and wherein a content of the oxygen in the aluminum oxide layer is within a range of more than about 1.5 times to about 2 times a content of the aluminum in the aluminum oxide layer.

A content of hydrogen in the aluminum oxide layer may be within a range of 1.5 atomic percentage (at %) to about 4 atomic percentage (at %).

A content of the hydrogen in the aluminum oxide layer may decrease in a thickness direction from the ferroelectric layer toward the plurality of gate electrodes.

The aluminum oxide layer may include a first aluminum oxide layer including the hydrogen and a second aluminum oxide layer including a lower hydrogen content than the first aluminum oxide layer, wherein the first aluminum oxide layer may be provided adjacent to the ferroelectric layer, and the second aluminum oxide layer may be provided adjacent to the gate electrode.

According to another aspect of at least one example embodiment, a method of forming a stacked structure including a substrate, a ferroelectric layer, a gate electrode, and an aluminum oxide layer between the ferroelectric layer and the gate, the method including supplying an aluminum precursor; removing the aluminum precursor that is not chemically deposited by performing a first purging; performing a hydrogen plasma treatment on a layer on which the aluminum precursor is deposited; forming the aluminum oxide layer by oxidizing the layer on which the aluminum precursor is deposited, the oxidizing the layer on which the aluminum precursor is deposited including providing an oxygen source on the layer on which the aluminum precursor is deposited; and removing unreacted substances and reaction by-products by performing a second purging.

The forming the aluminum oxide layer may include producing the aluminum oxide layer such that the aluminum oxide layer includes aluminum, oxygen, and hydrogen.

The forming the aluminum oxide layer may include producing the aluminum oxide layer such that a content of the oxygen in the aluminum oxide layer is more than about 1.5 times and about 2 times or less a content of the aluminum in the aluminum oxide layer.

The forming the aluminum oxide layer may include producing the aluminum oxide layer such that a content of the hydrogen in the aluminum oxide layer may be within a range of about 1.5 atomic percentage (at %) to about 4 atomic percentage (at %).

The forming the aluminum oxide layer may be performed at a temperature of 500° C. or lower.

The forming the aluminum oxide layer may include producing the aluminum oxide layer such that a concentration of hydrogen in the aluminum oxide layer in a region adjacent to the ferroelectric layer is greater than a concentration of hydrogen in the aluminum oxide layer in a region adjacent to the gate electrode.

The method may further include supplying, after the oxidizing the layer on which the aluminum precursor is deposited, an additional aluminum precursor on the substrate; removing the additional aluminum precursor that is not chemically deposited by performing a third purging; and depositing a second aluminum oxide layer by oxidizing the additional aluminum precursor, wherein the second aluminum oxide layer includes a lower hydrogen content than the aluminum oxide layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor device according to at least one example embodiment;

FIG. 2 is a cross-sectional view illustrating a semiconductor device according to at least one example embodiment;

FIG. 3 is a cross-sectional view illustrating a semiconductor device according to at least one example embodiment;

FIG. 4 is a cross-sectional view illustrating a semiconductor device according to at least one example embodiment;

FIG. 5A illustrates a ferroelectric layer, a first aluminum oxide layer, and a second aluminum oxide layer of a semiconductor device according to a first embodiment;

FIG. 5B illustrates voltage-current characteristics of the semiconductor device according to the first embodiment;

FIG. 6A illustrates a ferroelectric layer, a first aluminum oxide layer, and a second aluminum oxide layer of a semiconductor device according to a second embodiment;

FIG. 6B illustrates voltage-current characteristics of the semiconductor device according to the second embodiment;

FIG. 7 is a cross-sectional view illustrating a semiconductor device according to at least one example embodiment;

FIG. 8 is a cross-sectional view illustrating a semiconductor device according to at least one example embodiment;

FIG. 9 is a cross-sectional view illustrating a semiconductor device according to at least one example embodiment;

FIG. 10 is a cross-sectional view illustrating a semiconductor device according to at least one example embodiment;

FIG. 11 is a cross-sectional view illustrating a semiconductor device according to at least one example embodiment;

FIG. 12 is a flowchart illustrating a method of manufacturing the semiconductor device shown in FIG. 1;

FIG. 13 is a flowchart illustrating an example of an operation of depositing an aluminum oxide layer in FIG. 12 according to at least one example embodiment;

FIG. 14 is a flowchart illustrating a method of manufacturing the semiconductor device shown in FIG. 2;

FIG. 15 is a flowchart illustrating a method of manufacturing the semiconductor device shown in FIG. 8;

FIG. 16 is a flowchart illustrating a method of manufacturing the semiconductor device shown in FIG. 9;

FIG. 17 is a cross-sectional view illustrating a memory device according to at least one example embodiment;

FIG. 18 is a perspective view illustrating a schematic structure of a cell string in FIG. 17;

FIGS. 19 to 22 illustrate example cross-sections of memory cells applicable to the memory device shown in FIG. 17;

FIG. 23 is a schematic block diagram of a display device including a display driver integrated circuit (DDI) according to at least one example embodiment;

FIG. 24 is a block diagram of an electronic device according to at least one example embodiment;

FIG. 25 is a block diagram of an electronic device according to at least one example embodiment; and

FIGS. 26 and 27 are conceptual diagrams schematically showing a device architecture applicable to an electronic device according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. Like reference numerals in the drawings denote like components, and sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

Hereinafter, the term “on” or “above” may include not only one directly above another in contact but also one directly above another without contact. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. Singular expressions include plural expressions unless they are explicitly and differently specified in context. In addition, when a portion includes a component, a case may mean further including other components without excluding other components unless otherwise described.

The use of the term “above” and similar indicative terms may correspond to both singular and plural. When there is no explicit description or contrary description of operations constituting a method, these operations may be performed in an appropriate order, and may not be necessarily limited to the described order.

Also, in the specification, terms like “units” which denote functional elements that process at least one function or operation, may be realized by processing circuitry such as, hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

Connections of lines between components or connection members illustrated in the drawings exemplarily represent functional connection and/or physical or circuitry connections, and in a real apparatus, may be implemented by replaceable or additional various functional connections, physical connections, or circuitry connections.

The use of all examples or example terms is simply for describing a technical idea in detail, and the scope of the present disclosure is not limited by these examples or example terms unless limited by the claims.

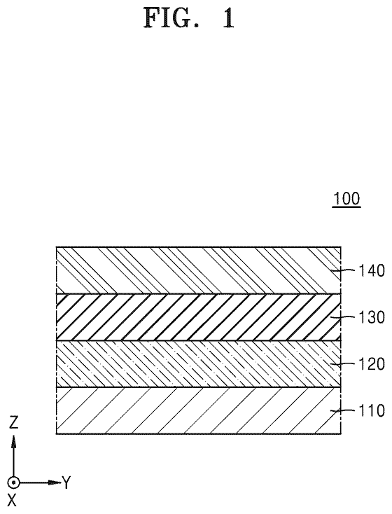

FIG. 1 is a cross-sectional view illustrating a semiconductor device 100 according to at least one example embodiment. The semiconductor device 100 shown in FIG. 1 may be (and/or be included in) a ferroelectric field effect transistor (FEFET). The semiconductor device 100 may constitute a memory cell of a memory device.

Referring to FIG. 1, the semiconductor device 100 may include a semiconductor substrate 110, a ferroelectric layer 120, an aluminum oxide layer 130, and a gate electrode 140.

An upper region of the semiconductor substrate 110 may be a channel region corresponding to the gate electrode 140, and a source region (not shown) and a drain region (not shown) may be provided on both sides of the channel region, respectively.

The semiconductor substrate 110 may include, for example, an elemental semiconductor (e.g., a Group IV semiconductor, such as Si, Ge, and/or SiGe), and/or a compound semiconductor (e.g., a Group III-V semiconductor compound). The semiconductor substrate 110 may also include, for example, an oxide semiconductor, a nitride semiconductor, an oxynitride semiconductor, a two-dimensional (2D) semiconductor material, quantum dots, and/or an organic semiconductor. In these cases, the oxide semiconductor may include, for example, InGaZnO and/or the like, the 2D semiconductor material may include, for example, transition metal dichalcogenide (TMD) and/or graphene, and the quantum dots may include colloidal quantum dots, nanocrystal structures, and/or the like. However, these are just examples, and the example embodiments are not limited thereto.

The semiconductor substrate 110 may further include a dopant. The dopant may include a p-type dopant and/or an n-type dopant. For example, in the case wherein the semiconductor substrate 110 includes a Group IV semiconductor, p-type dopant may include, for example, a Group III element, such as B, Al, Ga, and/or In, and the n-type dopant may include, for example, a Group V element, such as P, As, and/or Sb. For a specific example, the semiconductor substrate 110 may be a p-Si substrate in which Si is doped with a p-type dopant or an n-Si substrate in which Si is doped with an n-type dopant. However, this is just an example.

The gate electrode 140 is provided above the semiconductor substrate 110. The gate electrode 140 may include a conductive material, for example, metal and/or metal nitride. The metal may include, for example, aluminum (Al), tungsten (W), molybdenum (Mo), titanium (Ti), and/or tantalum (Ta), and the metal nitride may include, for example, titanium nitride (TiN) and/or tantalum nitride (TaN).

The gate electrode 140 may also include metal carbide, polysilicon, and/or a 2D conductive material. The metal carbide may be aluminum and/or silicon-doped metal carbide. As a specific example, the metal carbide may include TiAIC, TaAIC, TiSiC, and/or TaSiC. The gate electrode 140 may have a structure in which a plurality of materials are stacked. For example, the gate electrode 140 may have a stacked structure of metal nitride/metal layers, such as TiN/Al layers, and/or a stacked structure of metal nitride/metal carbide/metal layers, such as TiN/TiAlC/W layers.

The ferroelectric layer 120 may be provided between the semiconductor substrate 110 and the gate electrode 140 in a direction (Z-axis direction) perpendicular to the semiconductor substrate 110, that is, in the thickness direction of the semiconductor substrate 110. The ferroelectric layer 120 may include a ferroelectric material. The ferroelectric material is a material having ferroelectricity by which internal electric dipole moments are aligned to maintain spontaneous polarization. The ferroelectric material has remnant polarization due to a dipole, such that polarization may remain even when an external electric field is not applied. In addition, in the ferroelectric material, the direction of polarization may be switched on a domain basis by an external electric field.

For example, the ferroelectric layer 120 may include a fluorite-based material, a perovskite-based material, and/or a combination thereof. For example, the fluorite-based material may include an oxide of at least one selected from Hf, Si, Al, Zr, Y, La, Gd, and Sr. As a specific example, the fluorite-based material may include hafnium oxide (HfO), zirconium oxide (ZrO), hafnium-zirconium oxide (HfZrO), and/or a combination thereof. For example, the perovskite may include, but is not limited to, PZT, BaTiO₃, PbTiO₃, and/or the like.

The ferroelectric layer 120 may include one or more of an orthorhombic crystal system crystal phase, a tetragonal crystal system crystal phase, and a monoclinic crystal system crystal phase. For example, the ferroelectric layer 120 may include the orthorhombic crystal system crystal phase dominantly and/or in the largest proportion of all crystal phases. In at least some embodiments, the ferroelectric material may include a crystal including a crystal phase lacking an inversion center (e.g., is non-centrosymmetric). The ferroelectric layer 120 may further include a certain dopant. For example, the ferroelectric layer 120 may include a material in which a certain dopant is implanted into hafnium oxide (HfO), zirconium oxide (ZrO), hafnium-zirconium oxide (HfZrO), and/or a combination thereof. In this case, the certain dopant may include at least one of, for example, Zr, La, Al, Si, and Y. However, the examples are not limited thereto.

An aluminum oxide layer 130 may be provided on the ferroelectric layer 120. The semiconductor substrate 110, the ferroelectric layer 120, the aluminum oxide layer 130, and the gate electrode 140 may be sequentially provided in the direction (Z-axis direction) perpendicular to the semiconductor substrate 110. The aluminum oxide layer 130 may be a layer deposited on the ferroelectric layer 120 by being treated with hydrogen plasma, as described below.

The aluminum oxide layer 130 may include aluminum (Al), oxygen (O), and hydrogen (H). The oxygen atomic percentage (at %) in the aluminum oxide layer 130 may be more than approximately 1.5 times and approximately 2 times or less the aluminum atomic percentage (at %). In other words, in at least some embodiments, the oxygen atomic percentage (at %) of the aluminum oxide layer 130 may be referred to as being within a range of more than approximately 1.5 times to approximately 2 times (e.g., 1.5 times <O at %≤2 times) the aluminum atomic percentage (at %) of the aluminum oxide layer 130. That is, the ratio of the number of oxygen atoms to the number of aluminum atoms in the aluminum oxide layer 130 may exceed approximately 1.5 and may be approximately 2 or less. The hydrogen atomic percentage (at %) in the aluminum oxide layer 130 may exceed approximately 1.5 atomic percentage (at %) and may be approximately 4 atomic percentage (at %) or less. In other words, in at least some embodiments, the hydrogen atomic percentage (at %) of the aluminum oxide layer 130 may be referred as being within a range of 1.5 to 4 atomic percentage (at %) of the aluminum oxide layer 130. In at least some embodiments, the aluminum oxide layer 130 may further include deuterium.

The thickness of the aluminum oxide layer 130 may be within a range of approximately 0.3 nm to approximately 10 nm. In addition, for example, the density of the aluminum oxide layer 130 may be approximately 3.00 g/cm³ or more. For example, the density of the aluminum oxide layer 130 may exceed approximately 3.38 g/cm³. For example, the density of the aluminum oxide layer 130 may be approximately 3.40 g/cm³ or more. For example, the density of the aluminum oxide layer 130 may be approximately 3.45 g/cm³ or more. For example, the density of the aluminum oxide layer 130 may be less than approximately 3.95 g/cm³.

[Table 1] below shows the results of comparative analysis of the surface of an aluminum oxide layer not treated with hydrogen plasma and the surface of an aluminum oxide layer treated with hydrogen plasma by using X-ray photoelectron spectroscopy (XPS).

TABLE 1

| XPS | C1s | O1s | Al2p | O/Al |
|---|---|---|---|---|
| Aluminum oxide | 1.86 | 58.92 | 39.22 | 1.5 |
| layer not treated | | | | |
| with hydrogen | | | | |
| plasma | | | | |
| Aluminum oxide | 1.25 | 61.13 | 37.62 | 1.62 |
| layer treated with | | | | |
| hydrogen plasma | | | | |

Referring to [Table 1], the aluminum oxide layer treated with hydrogen plasma has fewer carbon (C1s) atoms, more oxygen (O1s) atoms, and fewer aluminum (A12p) atoms than the aluminum oxide layer not treated with hydrogen plasma. Therefore, the aluminum oxide layer treated with hydrogen plasma has a higher ratio (“O/Al”) of the number of oxygen atoms to the number of aluminum atoms than the aluminum oxide layer not treated with hydrogen plasma.

[Table 2] below shows the results of comparative analysis of the amount of thin film component elements in the aluminum oxide layer not treated with hydrogen plasma and the aluminum oxide layer treated with hydrogen plasma by using medium energy ion scattering spectrometer (MEIS).

TABLE 2

| | Al | O | H | | Density |
|---|---|---|---|---|---|
| MEIS | (at %) | (at %) | (at %) | O/Al | (g/cm³) |
| Aluminum oxide | 39.9 | 58.8 | 1.3 | 1.47 | 3.38 |
| layer not treated | | | | | |
| with hydrogen | | | | | |
| plasma | | | | | |
| Aluminum oxide | 38.8 | 59.2 | 2.0 | 1.52 | 3.45 |
| layer treated with | | | | | |
| hydrogen plasma | | | | | |

Referring to [Table 2], the aluminum oxide layer treated with hydrogen plasma has a smaller aluminum (Al) atomic percentage (at %), a larger oxygen (O) atomic percentage (at %), and a larger hydrogen (H) atomic percentage (at %) than the aluminum oxide layer not treated with hydrogen plasma. The aluminum oxide layer treated with hydrogen plasma has a higher ratio (“O/Al”) of the oxygen atomic percentage (at %) to the aluminum atomic percentage (at %) than the aluminum oxide layer not treated with hydrogen plasma.

When an aluminum oxide layer is deposited on the ferroelectric layer 120 without a hydrogen plasma treatment process, a ligand, which fails to react in a reaction chamber when depositing an aluminum precursor and exists in the form of carbon and/or nitrogen, may act as a defect in the ferroelectric layer 120 and have a negative effect on the memory window of the semiconductor device 100. On the other hand, according to at least one example embodiment, hydrogen plasma treatment may be performed in the process of depositing the aluminum oxide layer 130 on the ferroelectric layer 120 to thereby reduce the amount of ligand that fails to react in the reaction chamber. Accordingly, the number of unwanted defects in the ferroelectric layer 120 are reduced and the memory window may be improved. In addition, the aluminum oxide layer 130 formed by hydrogen plasma treatment may also function as a charge trap layer that traps and retains charges introduced from surrounding layers, thereby further improving the memory window.

As such, in the semiconductor device 100 according to at least one example embodiment, the memory window may be improved by forming the aluminum oxide layer 130 treated with hydrogen plasma on the ferroelectric layer 120, and the reliability of the semiconductor device 100 may also be increased.

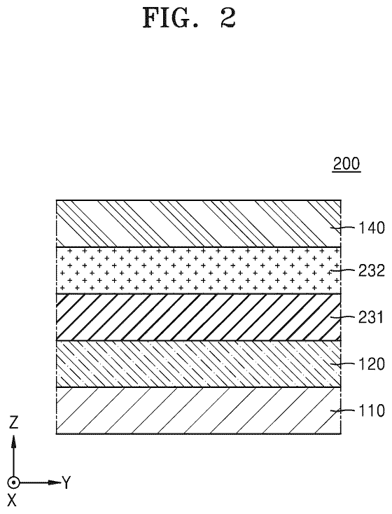

FIG. 2 is a cross-sectional view illustrating a semiconductor device 200 according to at least one example embodiment. Descriptions will be given by focusing on the differences from FIG. 1.

Referring to FIG. 2, a first aluminum oxide layer 231 is provided between the ferroelectric layer 120 and the gate electrode 140, and a second aluminum oxide layer 232 is provided between the first aluminum oxide layer 231 and the gate electrode 140. The semiconductor substrate 110, the ferroelectric layer 120, the first aluminum oxide layer 231, the second aluminum oxide layer 232, and the gate electrode 140 may be sequentially provided in the direction (Z-axis direction) perpendicular to the semiconductor substrate 110. In at least one embodiment, the thickness of the first aluminum oxide layer 231 and the second aluminum oxide layer 232 may be the same and/or substantially similar.

The first aluminum oxide layer 231 may be the same as and/or substantially similar to the aluminum oxide layer 130 shown in FIG. 1 described above. Accordingly, the first aluminum oxide layer 231 may include aluminum (Al), oxygen (O), and hydrogen (H). The oxygen atomic percentage (at %) in the first aluminum oxide layer 231 may be within a range of approximately 1.5 times to approximately 2 times the aluminum atomic percentage (at %). The hydrogen atomic percentage (at %) in the first aluminum oxide layer 231 may exceed approximately 1.5 atomic percentage (at %) and/or may be approximately 4 atomic percentage (at %) or less. In other words, at least some embodiments, the oxygen atomic percentage (at %) of the aluminum oxide layer 130 may be referred as being within of range of more than 1.5 times to 2 times (e.g., 1.5 times <O at %≤2 times) the aluminum atomic percentage (at %) of the aluminum oxide layer 130; and/or the hydrogen atomic percentage (at %) of the aluminum oxide layer 130 may be referred as being within a range of 1.5 to 4 atomic percentage (at %) of the aluminum oxide layer 130.

The second aluminum oxide layer 232 may include Al₂O₃. That is, the oxygen atomic percentage (at %) in the second aluminum oxide layer 232 may be 1.5 times the aluminum atomic percentage (at %). Accordingly, the oxygen content of the second aluminum oxide layer 232 may be less than the oxygen content of the first aluminum oxide layer 231. The oxygen content compared to the aluminum content in the second aluminum oxide layer 232 may be less than the oxygen content compared to the aluminum content in the first aluminum oxide layer 231. Specifically, the number of oxygen atoms compared to the number of aluminum atoms in the second aluminum oxide layer 232 may be less than the number of oxygen atoms compared to the number of aluminum atoms in the first aluminum oxide layer 231.

The hydrogen content of the second aluminum oxide layer 232 may be less than the hydrogen content of the first aluminum oxide layer 231. For example, the second aluminum oxide layer 232 may not include hydrogen. Alternatively, the second aluminum oxide layer 232 may include hydrogen but at a lower atomic percentage compared to the first aluminum oxide layer 231. Specifically, the hydrogen atomic percentage (at %) of the second aluminum oxide layer 232 may be less than the hydrogen atomic percentage (at %) of the first aluminum oxide layer 231.

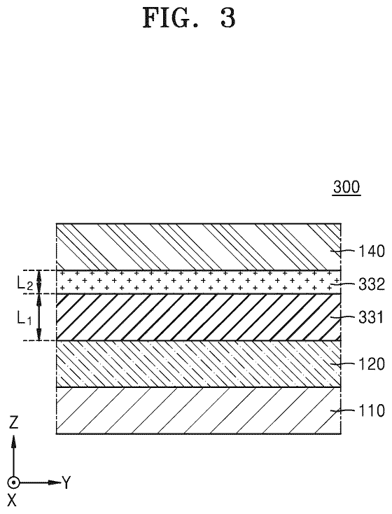

FIG. 3 is a cross-sectional view illustrating a semiconductor device 300 according to at least one example embodiment. Descriptions will be given by focusing on the differences from FIG. 2, and therefore repeat descriptions omitted.

Referring to FIG. 3, a first aluminum oxide layer 331 is provided between the ferroelectric layer 120 and the gate electrode 140, and a second aluminum oxide layer 332 is provided between the first aluminum oxide layer 331 and the gate electrode 140. In this case, a thickness L2 of the second aluminum oxide layer 332 may be greater than a thickness L1 of the first aluminum oxide layer 331. For example, the thickness L2 of the second aluminum oxide layer 332 may be approximately twice the thickness L1 of the first aluminum oxide layer 331. For example, the thickness L2 of the second aluminum oxide layer 332 may be about 2 nm, and the thickness L1 of the first aluminum oxide layer 331 may be about 1 nm.

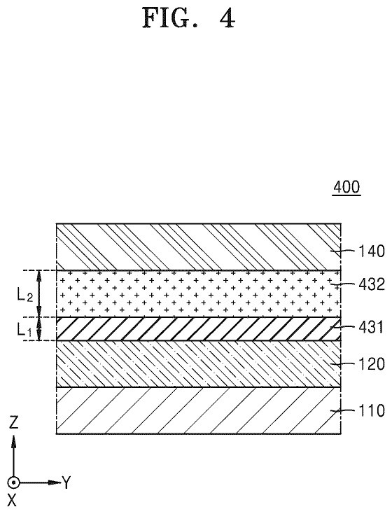

FIG. 4 is a cross-sectional view illustrating a semiconductor device 400 according to at least one example embodiment. Descriptions will be given by focusing on the differences from FIGS. 2 and 3, and therefore repeat descriptions omitted.

Referring to FIG. 4, a first aluminum oxide layer 431 is provided between the ferroelectric layer 120 and the gate electrode 140, and a second aluminum oxide layer 432 is provided between the first aluminum oxide layer 431 and the gate electrode 140. In this case, a thickness L1 of the first aluminum oxide layer 431 may be greater than a thickness L2 of the second aluminum oxide layer 432. For example, the thickness L1 of the first aluminum oxide layer 431 may be approximately twice the thickness L2 of the second aluminum oxide layer 432. For example, the thickness L1 of the first aluminum oxide layer 431 may be about 2 nm, and the thickness L2 of the second aluminum oxide layer 432 may be about 1 nm.

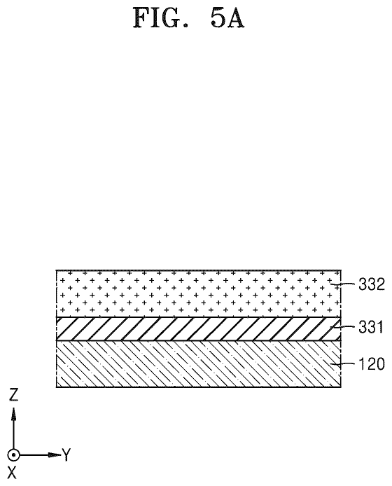

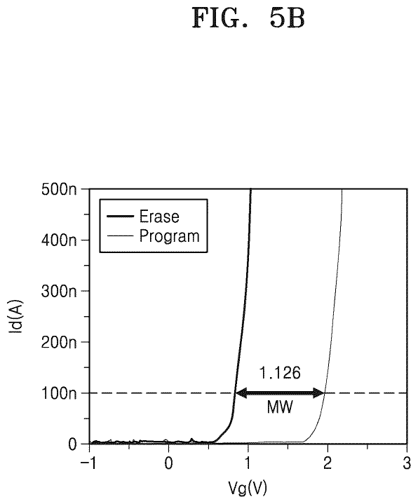

FIG. 5A illustrates the ferroelectric layer 120, the first aluminum oxide layer 331, and the second aluminum oxide layer 332 of a semiconductor device according to a first embodiment. In this case, the ferroelectric layer 120 includes hafnium-zirconium oxide having a thickness of 7 nm, the first aluminum oxide layer 331 includes hydrogen-treated aluminum oxide having a thickness of 1 nm, and the second aluminum oxide layer 332 includes non-hydrogen-treated aluminum oxide (i.e., Al₂O₃) having a thickness of 2 nm. FIG. 5B illustrates voltage-current characteristics of the semiconductor device according to the first embodiment. FIG. 5B shows the voltage-current characteristics measured during the erase and program operations of the semiconductor device, and the same applies below. Referring to FIG. 5B, a memory window MW of the semiconductor device according to the first embodiment is approximately 1.126V, which is higher than that of a semiconductor device including only a ferroelectric layer and/or a semiconductor device including a ferroelectric layer and a non-hydrogen-treated aluminum oxide layer (that is, an aluminum oxide layer not treated with hydrogen).

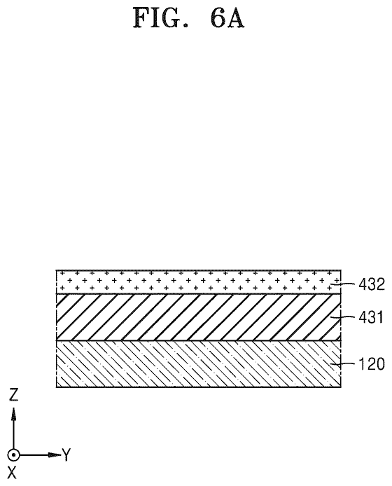

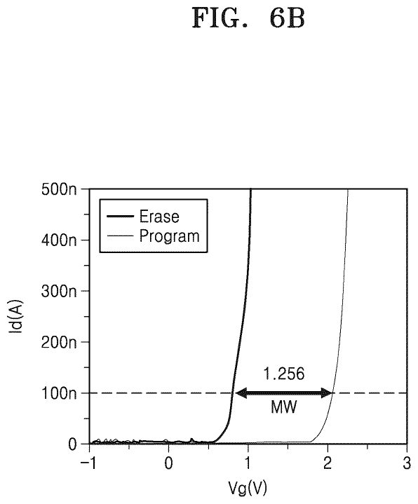

FIG. 6A illustrates the ferroelectric layer 120, the first aluminum oxide layer 431, and the second aluminum oxide layer 432 of a semiconductor device according to a second embodiment. In this case, the ferroelectric layer 120 includes hafnium-zirconium oxide having a thickness of 7 nm, the first aluminum oxide layer 431 includes hydrogen-treated aluminum oxide having a thickness of 2 nm, and the second aluminum oxide layer 432 includes non-hydrogen-treated aluminum oxide (i.e., Al₂O₃) having a thickness of 1 nm. FIG. 6B illustrates voltage-current characteristics of the semiconductor device according to the second embodiment. Referring to FIG. 6B, a memory window MW of the semiconductor device according to the second embodiment is approximately 1.256V. It can be seen that the memory window MW of the semiconductor device according to the second embodiment is improved compared to the memory window MW of the semiconductor device according to the first embodiment described above. From this, it can be seen that the thicker the first aluminum oxide layer treated with hydrogen is, the more the memory window is improved.

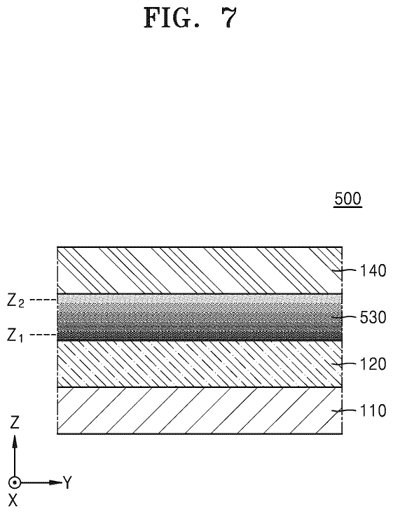

FIG. 7 is a cross-sectional view illustrating a semiconductor device 500 according to at least one example embodiment.

Referring to FIG. 7, an aluminum oxide layer 530 is provided between the ferroelectric layer 120 and the gate electrode 140. In this case, the aluminum oxide layer 530 may include aluminum (Al), oxygen (O), and hydrogen (H). The oxygen atomic percentage (at %) in the aluminum oxide layer 530 may be more than approximately 1.5 times and approximately 2 times or less the aluminum atomic percentage (at %). The hydrogen atomic percentage (at %) in the aluminum oxide layer 530 may exceed approximately 1.5 atomic percentage (at %) and may be approximately 4 atomic percentage (at %) or less. In other words, at least some embodiments, the oxygen atomic percentage (at %) of the aluminum oxide layer 530 may be referred as being 1.5 times <O at %≤2 times the aluminum atomic percentage (at %) of the aluminum oxide layer 130; and/or, the hydrogen atomic percentage (at %) of the aluminum oxide layer 130 may be referred as being within a range of 1.5 to 4 atomic percentage (at %) of the aluminum oxide layer 130.

The aluminum oxide layer 530 may be configured such that the oxygen content thereof gradually decreases from the ferroelectric layer 120 toward the gate electrode 140 in a thickness direction (Z-axis direction). Specifically, the aluminum oxide layer 530 may be configured such that the ratio of the number of oxygen atoms to the number of aluminum atoms gradually decreases from the ferroelectric layer 120 toward the gate electrode 140 in the thickness direction (Z-axis direction). For example, the ratio of the number of oxygen atoms to the number of aluminum atoms at the first position Z1 close to the ferroelectric layer 120 may be greater than the ratio of the number of oxygen atoms to the number of aluminum atoms at the second position Z2 close to the gate electrode 140. That is, the ratio of the number of oxygen atoms to the number of aluminum atoms may gradually decrease from the first position Z1 to the second position Z2.

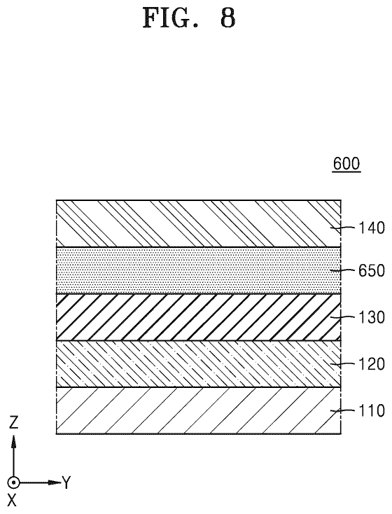

FIG. 8 is a cross-sectional view illustrating a semiconductor device 600 according to at least one example embodiment.

Referring to FIG. 8, an aluminum oxide layer 130 is provided between the ferroelectric layer 120 and the gate electrode 140. In this case, the aluminum oxide layer 130 is the same as and/or substantially similar to the aluminum oxide layer 130 shown in FIG. 1, and thus, repeat descriptions may be omitted.

The semiconductor device 600 may further include a current leakage prevention layer 650 between the aluminum oxide layer 130 and the gate electrode 140. Alternatively, the current leakage prevention layer 650 may be provided between the ferroelectric layer 120 and the aluminum oxide layer 130. The current leakage prevention layer 650 may block and/or reduce leakage current that may flow from the gate electrode 140 toward the aluminum oxide layer 130. The current leakage prevention layer 650 may include magnesium oxide, silicon oxide, yttrium oxide, lanthanum oxide, and/or a combination thereof. For example, the current leakage prevention layer 650 may include MgO, SiO, YO, LaO, and/or a combination thereof.

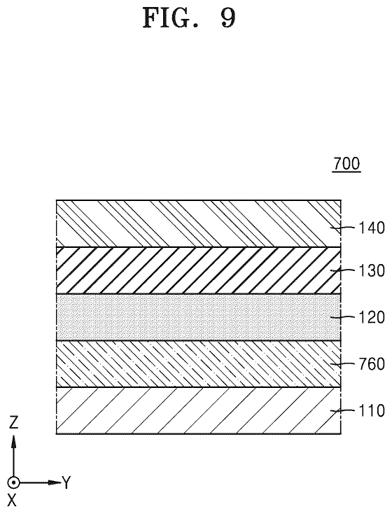

FIG. 9 is a cross-sectional view illustrating a semiconductor device 700 according to at least one example embodiment. Descriptions will be given by focusing on the differences from FIG. 1.

Referring to FIG. 9, the semiconductor device 700 may further include an insulating layer 760 provided on the surface of the semiconductor substrate 110. The insulating layer 160 may include oxide and/or oxynitride of a semiconductor material constituting the semiconductor substrate 110. For example, the insulating layer 160 may include SiO₂, GeO₂, SiGeO₄, SiON, GeON, SiGeON, and/or the like. However, this is just an example.

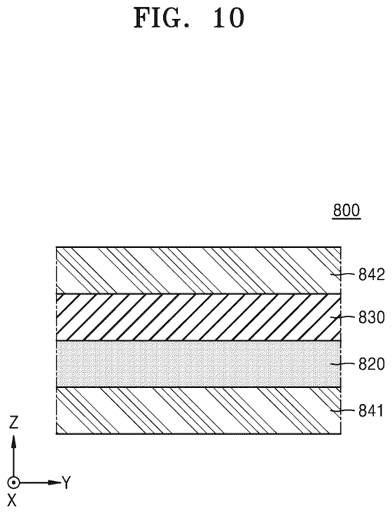

FIG. 10 is a cross-sectional view illustrating a semiconductor device 800 according to at least one example embodiment.

Referring to FIG. 10, the semiconductor device 800 may include a first electrode 841 and a second electrode 842 that are spaced apart from each other, a ferroelectric layer 820 provided between the first electrode 841 and the second electrode 842, and an aluminum oxide layer 830 provided between the ferroelectric layer 820 and the second electrode 842. In this case, the ferroelectric layer 820 and the aluminum oxide layer 830 may be, respectively, the same as and/or substantially similar to the ferroelectric layer 120 and the aluminum oxide layer 130 shown in FIG. 1 described above. Additionally, the first electrode 841 and the second electrode 842 may include a conductive material, for example, metal, metal nitride, metal carbide, polysilicon, and/or a 2D conductive material. The first electrode 841 and the second electrode 842 may include the same and/or different conductive materials. Additionally, structures similar to the stacked structure shown in FIGS. 2 to 3, 9, and 10 described above, wherein the substrate 110 is replaced with the first electrode 841, may also apply to the present example.

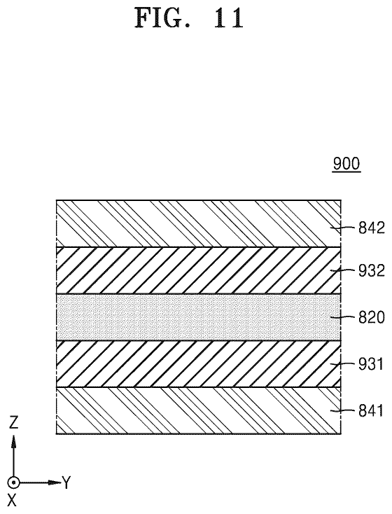

FIG. 11 is a cross-sectional view illustrating a semiconductor device 900 according to another example. Descriptions will be given by focusing on the differences from FIG. 10.

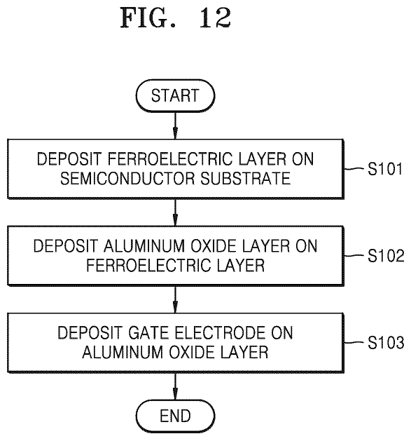

Referring to FIG. 11, a first aluminum oxide layer 931 is provided between the first electrode 841 and the ferroelectric layer 820, and a second aluminum oxide layer 932 is provided between the second electrode 842 and the ferroelectric layer 820. In this case, each of the first and second aluminum oxide layers 931 and 932 are the same as and/or substantially similar to the aluminum oxide layer 830 shown in FIG. 12.

FIG. 12 is a flowchart illustrating a method of manufacturing the semiconductor device 100 (or stacked structure) according to the example embodiment shown in FIG. 1.

Referring to FIG. 12, the ferroelectric layer 120 may be deposited on the semiconductor substrate 110 (operation S101). The ferroelectric layer 120 may be stacked in the thickness direction of the semiconductor substrate 110. The ferroelectric layer 120 may be manufactured by forming, on the semiconductor substrate 110, an amorphous layer having the same composition as the ferroelectric layer 120 and annealing the amorphous layer.

The amorphous layer may be formed through an atomic layer deposition (ALD) method. For example, a hafnium source, a zirconium source, and an oxygen source, including precursors may be used. For example, the precursors may include at least one of Hf(OtBu)₄, Tetrakis Ethyl Methyl Amino Hafnium (TEMAH), Tetrakis Di-Methyl Amino Hafnium (TDMAH), Tetrakis Di-Ethyl Amino Hafnium (TDEAH), and a combination thereof may be used as a ligand in the hafnium source. However, the examples are not limited thereto. In addition, at least one of Zr(OtBu)₄, Tetrakis Ethyl Methyl Amino Zirconium (TEMAZ), Tetrakis Di-Methyl Amino Zirconium (TDMAZ), Tetrakis Di-Ethyl Amino Zirconium (TDEAZ), and/or a combination thereof may be used as a ligand in the zirconium source. However, the disclosure is not limited thereto. In addition, at least one selected from the group consisting of O₃, H₂O, O₂, N₂O, O₂ plasma, and a combination thereof may be used as the oxygen source. However, the disclosure is not limited thereto.

The annealing may be performed under appropriate conditions where the amorphous layer may be converted into a ferroelectric layer. For example, the annealing may be performed under conditions where the amorphous layer may be crystallized into an orthorhombic crystal system crystal phase. For example, the annealing may be performed at a temperature ranging from about 400° C. to about 1100° C., but is not limited thereto. The annealing may be performed for a period of about 1 nano-seconds, 1 micro-seconds, 0.001 seconds, 0.01 seconds, 0.05 seconds, 0.1 seconds, 0.5 seconds, 1 seconds, 3 seconds, and/or 5 seconds to about 10 minutes, 5 minutes, 1 minutes, and/or 30 seconds, but is not limited thereto.

After the ferroelectric layer 120 is deposited on the semiconductor substrate 110, the aluminum oxide layer 130 may be deposited on the ferroelectric layer 120 (operation S102). The aluminum oxide layer 130 may be stacked in the thickness direction of the semiconductor substrate 110. After the aluminum oxide layer 130 is deposited on the ferroelectric layer 120, the gate electrode 140 may be deposited on the aluminum oxide layer 130 (operation S103). The semiconductor substrate 110, the ferroelectric layer 120, the aluminum oxide layer 130, and the gate electrode 140 may be stacked in this order in the thickness direction of the semiconductor substrate 110 to form a stacked structure.

Alternatively, by performing annealing after forming an amorphous layer on the semiconductor substrate 110 using an ALD method, forming an aluminum oxide layer 130 on the amorphous layer, and forming a gate electrode 140 on the aluminum oxide layer 130, the amorphous layer may be crystallized to form a stacked structure including the semiconductor substrate 110, the ferroelectric layer 120, the aluminum oxide layer 130, and the gate electrode 140.

Alternatively, by forming an amorphous layer on the semiconductor substrate 110 and performing a first annealing wherein amorphous layer remains mostly amorphous, and then forming an aluminum oxide layer 130 on the amorphous layer, depositing a gate electrode 140 on the aluminum oxide layer 130, and performing second annealing wherein the amorphous layer is converted into a ferroelectric layer, a stacked structure including the semiconductor substrate 110, the ferroelectric layer 120, the aluminum oxide layer 130, and the gate electrode 140 may be formed.

Below, for convenience, the case in which the ferroelectric layer 120 is formed on the semiconductor substrate 110 will be described as an example. However, the same may apply to various embodiments, such as forming an amorphous layer on the semiconductor substrate 110 and depositing the aluminum oxide layer 130 on the amorphous layer.

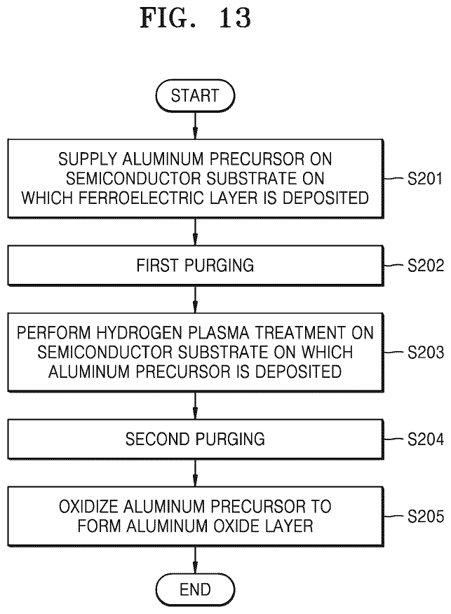

FIG. 13 is a flowchart illustrating at least one example embodiment of operation S102 of depositing the aluminum oxide layer 130 in FIG. 12.

Referring to FIG. 13, an aluminum precursor may be supplied to the semiconductor substrate 110 on which the ferroelectric layer 120 is deposited (operation S201). A portion of the aluminum precursor may be chemically adsorbed on the surface of the semiconductor substrate 110 and may form an atomic layer using an ALD method, and the remaining portion of the aluminum precursor may be physically adsorbed on the surface of the ferroelectric layer 120.

After the aluminum precursor is supplied to the semiconductor substrate 110 on which the ferroelectric layer 120 is deposited, first purging may be performed by supplying a purge gas (operation S202). During this process, an aluminum precursor that is not adsorbed may be removed. However, a ligand that fails to react when depositing the aluminum precursor on the semiconductor substrate 110 may exist in the form of carbon and/or nitrogen.

After the first purging is performed by supplying a purge gas to the semiconductor substrate 110, hydrogen plasma treatment may be performed on the semiconductor substrate 110 on which the aluminum precursor is deposited (operation S203). In this process, hydrogen plasma gas may react with carbon and/or nitrogen to generate reaction by-products (e.g., carbon compounds (e.g., CH4) and/or nitrogen compounds (e.g., NH3)). After hydrogen plasma treatment of the semiconductor substrate 110 on which the aluminum precursor is deposited, second purging may be performed by supplying a purge gas (operation S204). In this process, the reaction by-products may be removed. Thereafter, the aluminum precursor deposited on the semiconductor substrate 110 may be oxidized to form the aluminum oxide layer 130 (operation S205). Depositing the aluminum oxide layer 130 may be performed at a temperature of 500° C. or lower. In at least some embodiments, the maximum process temperature in the depositing the aluminum oxide layer 130 may be 500° C. or lower.

Operations S201 to S205 of forming the aluminum oxide layer 130 shown in FIG. 13 may constitute one cycle, and this cycle may be repeatedly performed to form the aluminum oxide layer 130 having a desired thickness.

When repeatedly performing operations S201 to S205 of forming the aluminum oxide layer 130 shown in FIG. 13, hydrogen plasma treatment may be performed such that the hydrogen content of a portion of the aluminum oxide layer 130 close to the ferroelectric layer 120 is greater than the hydrogen content of a portion of the aluminum oxide layer 130 close to the gate electrode 140. That is, hydrogen plasma treatment may be performed such that the hydrogen content of the aluminum oxide layer 130 decreases from the ferroelectric layer 120 toward the gate electrode 140.

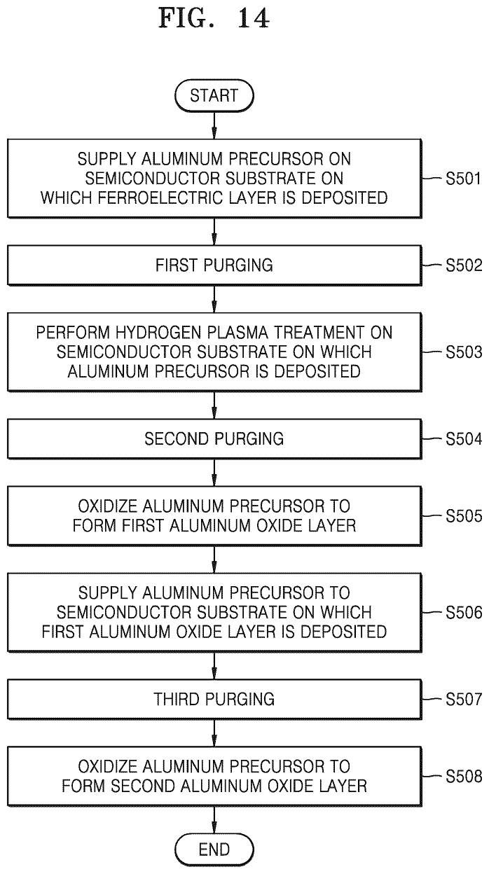

FIG. 14 is a flowchart illustrating at least one example embodiment of depositing the first and second aluminum oxide layers 231 and 232 in the semiconductor device 200 according to the example embodiment shown in FIG. 2.

Referring to FIG. 14, after the ferroelectric layer 120 is deposited on the semiconductor substrate 110 (operation S501), first purging may be performed (operation S502), and after hydrogen plasma treatment of the semiconductor substrate 110 on which an aluminum precursor is deposited (operation S503), second purging may be performed (operation S504), and then, the first aluminum oxide layer 231 may be formed by oxidizing the aluminum precursor (operation S505). Operations S501 to S505 of forming the first aluminum oxide layer 231 in FIG. 14 may be repeatedly performed to form the first aluminum oxide layer 231 having a desired thickness.

After the first aluminum oxide layer 231 is formed (operation S505), an aluminum precursor may be additionally supplied to the semiconductor substrate 110 on which the first aluminum oxide layer 231 is deposited (operation S506). Thereafter, third purging may be performed by supplying a purge gas (operation S507). In this process, an aluminum precursor that is not chemically adsorbed on the first aluminum oxide layer 231 may be removed. Thereafter, the aluminum precursor may be oxidized to form the second aluminum oxide layer 232 on the first aluminum oxide layer 231 (operation S508). Hydrogen plasma treatment may be performed on the first aluminum oxide layer 231, and hydrogen plasma treatment may not be performed on the second aluminum oxide layer 232. Operations S506 to S508 of forming the second aluminum oxide layer 232 shown in FIG. 14 may be repeatedly performed to form the second aluminum oxide layer 232 having a desired thickness.

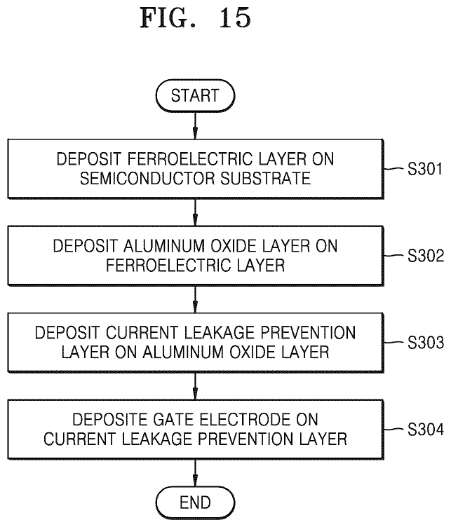

FIG. 15 is a flowchart illustrating a method of manufacturing the semiconductor device 600 according to the example embodiment shown in FIG. 8. Descriptions will be given by focusing on the differences from FIG. 12.

Referring to FIG. 15, after the ferroelectric layer 120 is deposited on the semiconductor substrate 110 (operation S301) and the aluminum oxide layer 130 is deposited on the ferroelectric layer 120 (operation S302), a current leakage prevention layer 650 may be further deposited on the aluminum oxide layer 130 (operation S303). After the current leakage prevention layer 650 is deposited on the aluminum oxide layer 130, the gate electrode 140 may be deposited on the current leakage prevention layer 650 (operation S304). Operations S301, S302, and S304 may be, respectively, the same as and/or substantially similar to operations S101, S102, and S03 of FIG. 12, and therefore repeat descriptions thereof omitted.

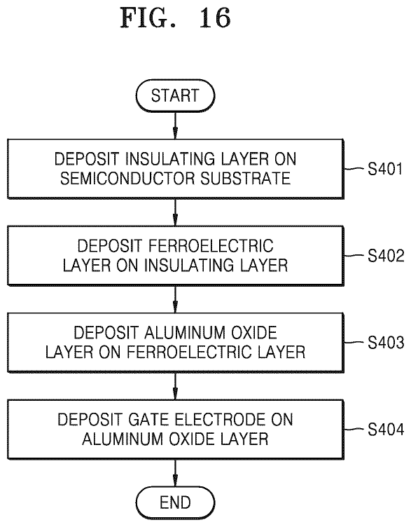

FIG. 16 is a flowchart illustrating a method of manufacturing the semiconductor device 700 according to the example embodiment shown in FIG. 9. Descriptions will be given by focusing on the differences from FIG. 12.

Referring to FIG. 16, operation S401 of depositing an insulating layer 760 on the semiconductor substrate 110 may be performed. Next, the ferroelectric layer 120 may be deposited on the insulating layer 760 (operation S402), the aluminum oxide layer 130 may be deposited on the ferroelectric layer 120 (operation S403), and then the gate electrode 140 may be deposited on the aluminum oxide layer 130 (operation S404). Operations S401, S402, and S404 may be, respectively, the same as and/or substantially similar to operations S101, S102, and S03 of FIG. 12, and therefore repeat descriptions thereof omitted.

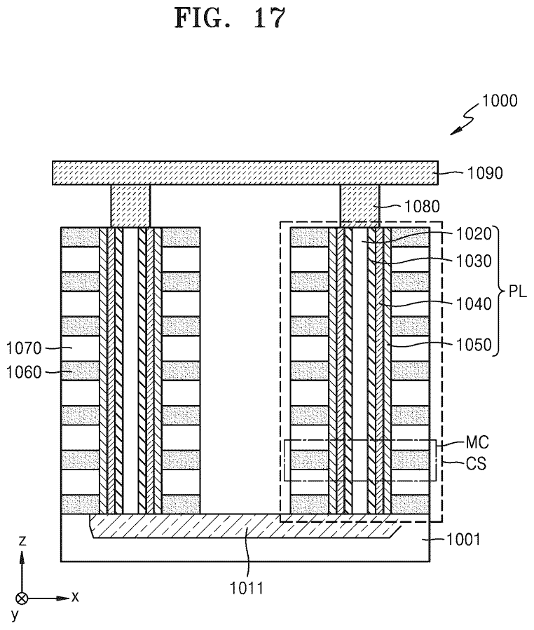

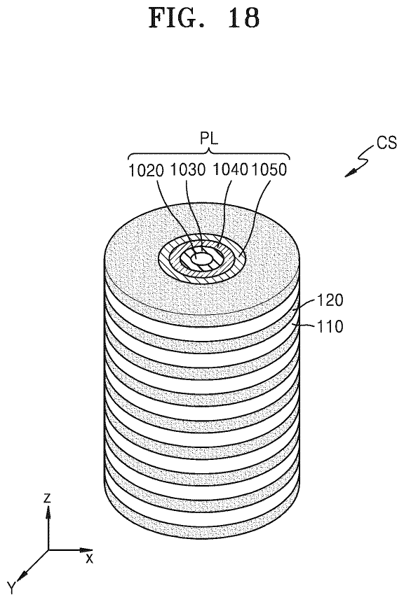

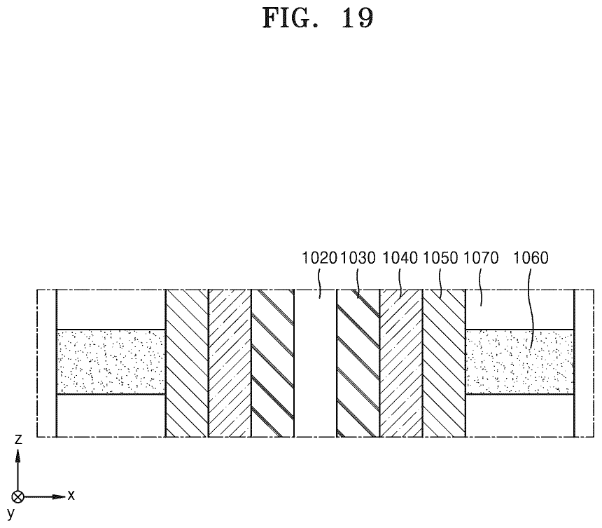

FIG. 17 is a cross-sectional view illustrating a memory device 1000 according to at least one example embodiment, and FIG. 18 is a perspective view illustrating a schematic structure of a cell string CS in FIG. 17. FIGS. 19 to 22 illustrate example cross-sections of memory cells that may be applied to the memory device 1000 shown in FIG. 17.

Referring to FIGS. 17 and 18, a plurality of cell strings CS may be arranged in a certain shape on a substrate 1001. FIG. 17 shows a case where two cell strings CS are arranged on the substrate 1001. However, the number of cell strings CS arranged on the substrate 1001 and their arrangement form may be changed in various ways. Each of the cell strings CS may include a cylindrical pillar PL, and a plurality of insulating layers 1070 and a plurality of gate electrodes 1060, which surround the pillar PL in a ring shape. The plurality of insulating layers 1070 and the plurality of gate electrodes 1060 may be alternately stacked in a direction perpendicular to the substrate 1001.

The substrate 1001 may include various materials. For example, the substrate 1001 may include, but is not limited to, a single crystal silicon substrate, a compound semiconductor substrate, and/or a silicon on insulator (SOI) substrate. In addition, the substrate 1001 may further include, for example, a doped region 1011, electronic elements such as transistors, and/or a peripheral circuit that selects and controls memory cells storing data.

The insulating layers 1070 may function as spacers for insulation between the gate electrodes 1060. The insulating layers 1070 not only may function as spacers to maintain a distance between the gate electrodes 1060 but also may prevent trapped charges from spreading to another cell. The insulating layer 1070 may include various insulating materials, such as silicon oxide and silicon nitride. The insulating layer 1070 may include one or more layers.

The gate electrodes 1060 may include a metal material and/or a highly doped silicon material. Each of the gate electrodes 1060 may be connected to one of a word line WL and a string select line SSL.

A through hole extending in a direction (Z-axis direction) perpendicular to the substrate 1001 is formed in the gate electrodes 1060 and the insulating layers 1070, and the pillar PL may be provided inside the through hole. The pillar PL may be provided with a drain 1080, which may include a silicon material doped with a certain type of impurity. For example, the drain 1080 may include a silicon material doped with an n-type impurity. A bit line 1090 may be provided in the drain 1080. The drain 1080 and the bit line 1090 may be connected to each other through contact plugs.

The pillar PL may include a plurality of layers. For example, the pillar PL may include an aluminum oxide layer 1050, a ferroelectric layer 1040, a channel layer 1030, and a filling layer 1020, which are sequentially stacked on the inner wall of the through hole in a direction parallel to the substrate 1001. In this case, the channel layer 1030, the ferroelectric layer 1040, the aluminum oxide layer 1050, and the gate electrode 1060 constitute a memory cell MC.

The gate electrode 1060, the aluminum oxide layer 1050, and the ferroelectric layer 1040 are respectively the same as and/or substantially similar the gate electrode 140, the aluminum oxide layer 130, and the ferroelectric layer 120 shown in FIG. 1, and thus, detailed descriptions thereof are omitted. Additionally, the stacked structure shown in FIGS. 2 to 3, 9, and 10 described above may also apply to the present example.

The channel layer 1030 may include a semiconductor material. For example, the channel layer 1030 may include an elemental semiconductor (e.g., a group IV semiconductor, such as Si, Ge, SiGe), and/or compound semiconductor (e.g., a group III-V semiconductor compound). The channel layer 1030 may include, for example, an oxide semiconductor, a nitride semiconductor, an oxynitride semiconductor, a 2D semiconductor material, quantum dots, and/or an organic semiconductor. In this case, the oxide semiconductor may include, for example, InGaZnO and/or the like, the 2D semiconductor material may include, for example, TMD and/or graphene, and the quantum dots may include colloidal quantum dots, nanocrystal structures, and/or the like. However, this is just an example, and the present example embodiments are not limited thereto.

The channel layer 1030 may further include a dopant. The dopant may include a p-type dopant or an n-type dopant. For example, in the case wherein the semiconductor substrate 110 includes a Group IV semiconductor, the p-type dopant may include, for example, a Group III element, such as B, Al, Ga, and/or In, and the n-type dopant may include, for example, a Group V element, such as P, As, and/or Sb.

The channel layer 1030 may be provided to extend in the direction perpendicular to the substrate 1001. The channel layer 1030 may be provided to have, for example, a cylindrical shape.

The ferroelectric layer 1040 may be provided to surround the channel layer 1030. The ferroelectric layer 1040 may be provided to extend in the direction perpendicular to the substrate 1001, and the aluminum oxide layer 1050 may be provided to surround the ferroelectric layer 1040. The ferroelectric layer 1040 and the aluminum oxide layer 1050 may each be provided to extend in the direction perpendicular to the substrate 1001. A plurality of gate electrodes 1060 may be provided outside the aluminum oxide layer 1050 to surround the aluminum oxide layer 1050.

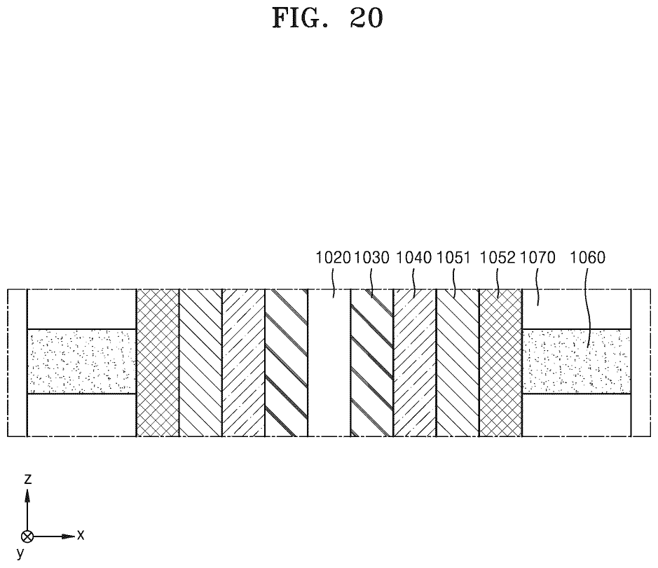

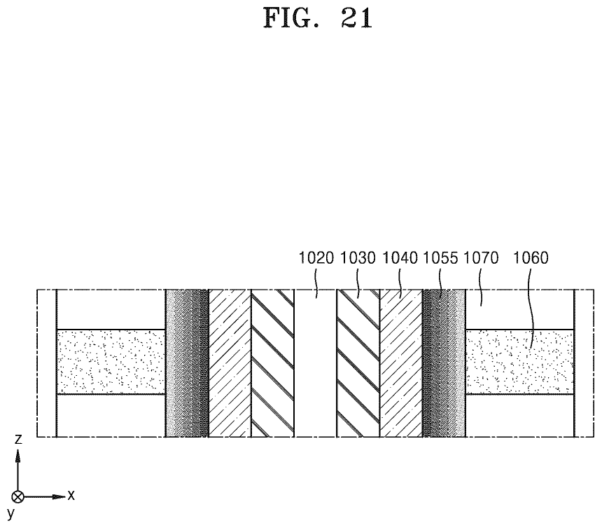

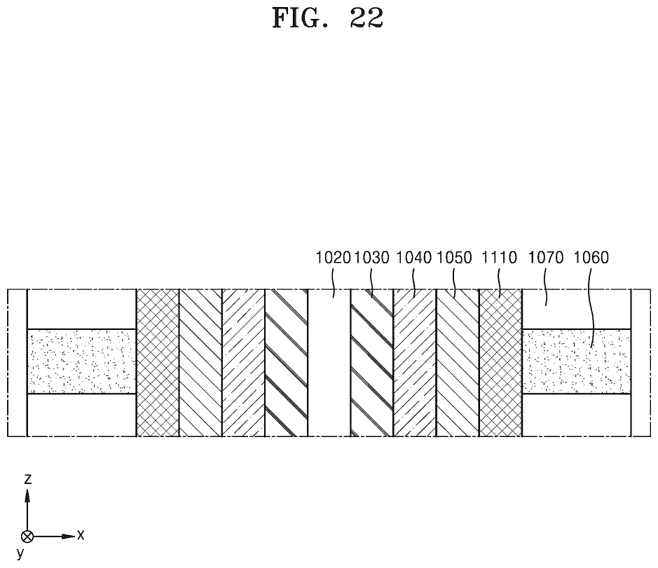

FIGS. 20 to 22 show example cross-sections of memory cells MC that may be applied to the memory device 1000 shown in FIG. 17. Referring to FIG. 20, the memory cell MC includes a channel layer 1030, a ferroelectric layer 1040, a first aluminum oxide layer 1051, a second aluminum oxide layer 1052, and a gate electrode 1060, which are sequentially stacked in the direction parallel to the substrate 1001. This was mentioned in the description of FIG. 2 above. Referring to FIG. 21, the memory cell MC includes a channel layer 1030, a ferroelectric layer 1040, an aluminum oxide layer 1055, and a gate electrode 1060, which are sequentially stacked in the parallel direction on the substrate 1001. This was mentioned in the description of FIG. 7 above. Referring to FIG. 22, the memory cell MC includes a channel layer 1030, a ferroelectric layer 1040, an aluminum oxide layer 1050, a current leakage prevention layer 1110, and a gate electrode, which are sequentially stacked in the direction parallel to the substrate 1001. This was mentioned in the description of FIG. 8 above.

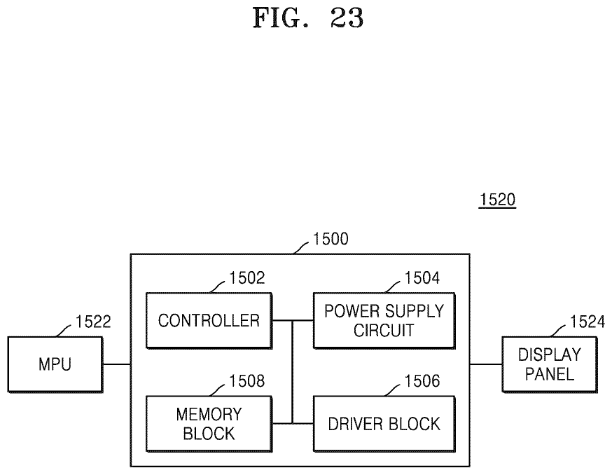

FIG. 23 is a schematic block diagram of a display device 1520 including a display driver integrated circuit (DDI) 1500 according to at least one example embodiment.

Referring to FIG. 23, the DDI 1500 may include a controller 1502, a power supply circuit 1504, a driver block 1506, and a memory block 1508. The controller 1502 receives and decodes commands issued from the main processing unit (MPU) 1522, and controls each block of the DDI 1500 to implement operations according to the commands. The power supply circuit 1504 generates a driving voltage in response to the control of the controller 1502. The driver block 1506 drives a display panel 1524 using the driving voltage generated by the power supply circuit 1504 in response to the control of the controller 1502. The display panel 1524 may be, for example, a liquid crystal display panel, an organic light-emitting device (OLED) display panel, and/or a plasma display panel. The memory block 1508 is a block that temporarily stores commands input to the controller 1502 or control signals output from the controller 1502, and/or stores necessary data, and may include memory, such as random access memory (RAM) and/or read only memory (ROM). For example, the memory block 1508 may include at least one of the semiconductor devices and memory device according to the embodiments described above.

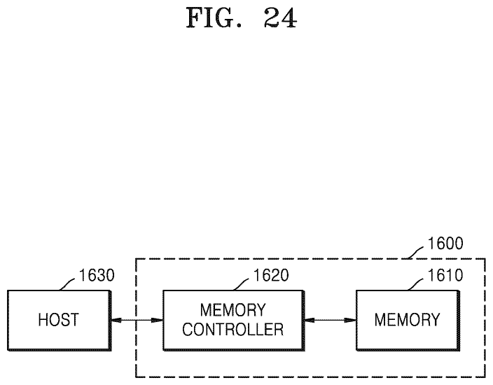

FIG. 24 is a block diagram of an electronic device 1600 according to at least one example embodiment.

Referring to FIG. 24, the electronic device 1600 includes a memory 1610 and a memory controller 1620. The memory controller 1620 may control the memory 1610 to read data from and/or write data to the memory 1610 in response to a request from a host 1630. The memory 1610 may include at least one of the semiconductor devices and memory device according to the embodiments described above.

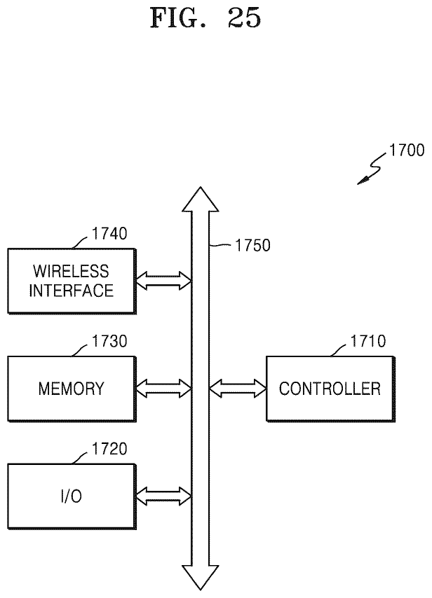

FIG. 25 is a block diagram of an electronic device 1700 according to at least one example embodiment.

Referring to FIG. 25, the electronic device 1700 may constitute a wireless communication device, and/or a device configured to transmit and/or receive information in a wireless environment. The electronic device 1700 may include a controller 1710, an input/output device (I/O) 1720, a memory 1730, and a wireless interface 1740, which are interconnected through a bus 1750.

The controller 1710 may include at least one of a microprocessor, a digital signal processor, and a similar processing device. The I/O device 1720 may include at least one of a keypad, a keyboard, and a display. The memory 1730 may be used to store instructions executed by the controller 1710. For example, the memory 1730 may be used to store user data. The electronic device 1700 may use the wireless interface 1740 to transmit/receive data through a wireless communication network. The wireless interface 1740 may include an antenna and/or a wireless transceiver. In some embodiments, the electronic device 1700 may be used in a communication interface protocol of a third generation communication system, such as code division multiple access (CDMA), global system for mobile communication (GSM), north American digital cellular (NADC), extended-time division multiple access (E-TDMA), and/or wide band code division multiple access (WCDMA). The memory 1730 of the electronic device 1700 may include at least one of the semiconductor devices and memory device according to the embodiments described above.

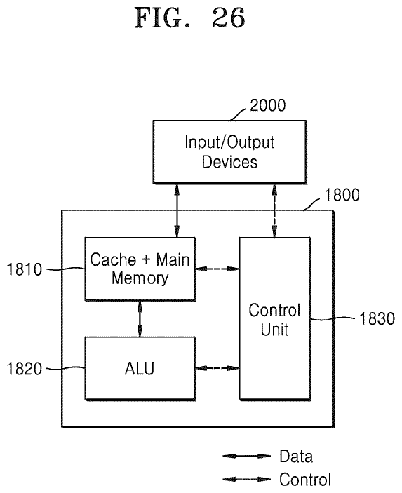

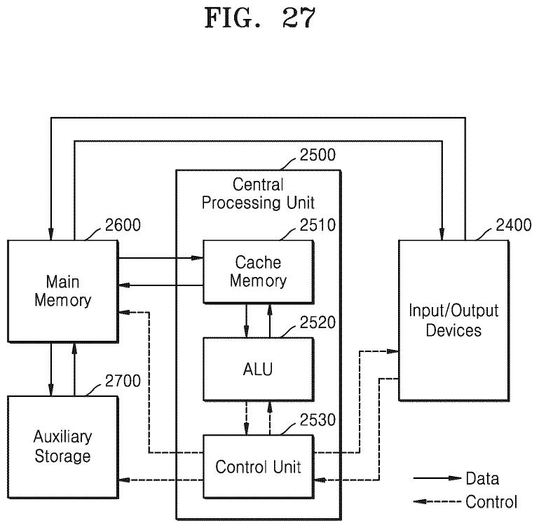

FIGS. 26 and 27 are conceptual diagrams schematically showing a device architecture that may be applied to an electronic device according to at least one example embodiment.

Referring to FIG. 26, an electronic device architecture 1800 may include a memory unit 1810 and a control unit 1830 and may further include an arithmetic logic unit (ALU) 1820. The memory unit 1810, the ALU 1820, and the control unit 1830 may be electrically connected to one another. For example, the electronic device architecture 1800 may be implemented as a single chip including the memory unit 1810, the ALU 1820, and the control unit 1830. Specifically, the memory unit 1810, the ALU 1820, and the control unit 1830 may be interconnected via a metal line in an on-chip and may directly communicate with one another. The memory unit 1810, the ALU 1820, and the control unit 1830 may be monolithically integrated on one substrate to form one chip. An input/output device 2000 may be connected to the electronic device architecture (chip) 1800. In addition, the memory unit 1810 may include both a main memory and a cache memory. The electronic device architecture (chip) 1800 may be an on-chip memory processing unit. The memory unit 1810, the ALU 1820, and/or the control unit 1830 may each independently include at least one of the semiconductor devices and memory device according to the embodiments described above.

In some cases, the electronic device architecture 1800 may be implemented in a form where computing unit devices and memory unit devices are adjacent to each other on one chip, without distinction of sub-units.

Referring to FIG. 27, a cache memory 2510, an ALU 2520, and a control unit 2530 may form a central processing unit (CPU) 2500, and the cache memory 2510 may include, for example, static random access memory (SRAM). Separately from the CPU 2500, a main memory 2600 and an auxiliary storage 2700 may be provided, and an input/output device 2400 may also be provided. The main memory 2600 may include, for example, at least one of the semiconductor devices and memory device according to the embodiments described above.

According to one or more example embodiments, a semiconductor device may be provided between a ferroelectric layer and a gate electrode and may include an aluminum oxide layer including aluminum, oxygen, and hydrogen and having an oxygen content that is greater than about 1.5 times and less than or equal to about 2 times an aluminum content, and thus, a memory cell having an improved memory window (MW) may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a semiconductor substrate;
a gate electrode;
a ferroelectric layer between the semiconductor substrate and the gate electrode; and
an aluminum oxide layer between the ferroelectric layer and the gate electrode,
wherein the aluminum oxide layer includes aluminum, oxygen, and hydrogen, and
wherein a content of the oxygen in the aluminum oxide layer is within of range of more than about 1.5 times to about 2 times a content of the aluminum in the aluminum oxide layer.

2. The semiconductor device of claim 1, wherein a content of the hydrogen in the aluminum oxide layer is within a range of 1.5 atomic percentage (at %) to about 4 atomic percentage (at %).

3. The semiconductor device of claim 1, wherein a thickness of the aluminum oxide layer is within a range of about 0.3 nm to about 10 nm.

4. The semiconductor device of claim 1, wherein a density of the aluminum oxide layer is within a range of about 3.00 g/cm³ to about 3.95 g/cm³.

5. The semiconductor device of claim 1, further comprising:
a current leakage prevention layer between the aluminum oxide layer and the gate electrode,
wherein the current leakage prevention layer includes at least one of MgO, SiO, YO, LaO, and/or a combination thereof.

6. The semiconductor device of claim 1, further comprising:
a current leakage prevention layer between the ferroelectric layer and the aluminum oxide layer,
wherein the current leakage prevention layer includes at least one of MgO, SiO, YO, LaO, and/or a combination thereof.

7. The semiconductor device of claim 1, wherein the ferroelectric layer includes at least one of hafnium oxide, zirconium oxide, hafnium-zirconium oxide, perovskite, and/or a combination thereof.

8. The semiconductor device of claim 1, wherein a content of the hydrogen in the aluminum oxide layer decreases in a thickness direction from the ferroelectric layer toward the gate electrode.

9. The semiconductor device of claim 1, wherein the aluminum oxide layer includes a first aluminum oxide layer including the hydrogen and a second aluminum oxide layer including a lower hydrogen content than the first aluminum oxide layer,
wherein the second aluminum oxide layer is between the first aluminum oxide layer and the gate electrode, and
wherein a thickness of the second aluminum oxide layer is greater than a thickness of the first aluminum oxide layer.

10. A memory device comprising:
a substrate;
a plurality of gate electrodes stacked in a direction perpendicular to the substrate;
a channel layer extending through the plurality of gate electrodes in the direction perpendicular to the substrate;
a ferroelectric layer on the channel layer such that the ferroelectric layer is between the channel layer and the plurality of gate electrodes; and
an aluminum oxide layer on the ferroelectric layer such that the aluminum oxide layer is between the ferroelectric layer and the plurality of gate electrodes; and
wherein the aluminum oxide layer includes aluminum, oxygen, and hydrogen, and
wherein a content of the oxygen in the aluminum oxide layer is within a range of more than about 1.5 times to about 2 times a content of the aluminum in the aluminum oxide layer.

11. The memory device of claim 10, wherein a content of the hydrogen in the aluminum oxide layer is within of range of about 1.5 atomic percentage (at %) to about 4 atomic percentage (at %).

12. The memory device of claim 10, wherein a content of the hydrogen in the aluminum oxide layer decreases in a thickness direction from the ferroelectric layer toward the plurality of gate electrodes.

13. The memory device of claim 10, wherein the aluminum oxide layer includes a first aluminum oxide layer including the hydrogen and a second aluminum oxide layer including a lower hydrogen content than the first aluminum oxide layer,
wherein the second aluminum oxide layer is between the first aluminum oxide layer and the gate electrode.

14. A method of forming a stacked structure comprising a substrate, a ferroelectric layer, a gate electrode, and an aluminum oxide layer between the ferroelectric layer and the gate electrode, the method comprising:
supplying an aluminum precursor;
removing the aluminum precursor that is not chemically deposited by performing a first purging;
performing a hydrogen plasma treatment on a layer on which the aluminum precursor is deposited;
forming the aluminum oxide layer by oxidizing the layer on which the aluminum precursor is deposited, the oxidizing the layer on which the aluminum precursor is deposited including providing an oxygen source on the layer on which the aluminum precursor is deposited; and
removing unreacted substances and reaction by-products by performing a second purging.

15. The method of claim 14, wherein the forming the aluminum oxide layer includes producing the aluminum oxide layer such that the aluminum oxide layer includes aluminum, oxygen, and hydrogen.

16. The method of claim 14, wherein the oxidizing the layer on which the aluminum precursor includes producing the aluminum oxide layer such that a content of oxygen in the aluminum oxide layer is within a range of more than about 1.5 times to about 2 times a content of aluminum in the aluminum oxide layer.

17. The method of claim 14, wherein the forming the aluminum oxide layer includes producing the aluminum oxide layer such that a content of hydrogen in the aluminum oxide layer is within a range of about 1.5 atomic percentage (at %) to about 4 atomic percentage (at %).

18. The method of claim 14, wherein the forming the aluminum oxide layer is performed at a temperature of about 500° C. or lower.

19. The method of claim 14, wherein the forming the aluminum oxide layer includes forming the aluminum oxide layer such that a concentration of hydrogen in the aluminum oxide layer in a region adjacent to the ferroelectric layer is greater than a concentration of hydrogen in the aluminum oxide layer in a region adjacent to the gate electrode.

20. The method of claim 14, further comprising:
supplying, after the oxidizing the layer on which the aluminum precursor is deposited, an additional aluminum precursor on the substrate;
removing the additional aluminum precursor that is not chemically deposited by performing a third purging; and
depositing a second aluminum oxide layer by oxidizing the additional aluminum precursor,
wherein the second aluminum oxide layer includes a lower hydrogen content than the aluminum oxide layer.
